(19) United States
(12) Patent Application Publication
(10) Pub. No.: US 2013/0187232 A1
(43) Pub. Date: Jul. 25, 2013

(54) SEMICONDUCTOR DEVICE

(71) Applicant: SEIKO INSTRUMENTS INC., Chiba (JP)

(72) Inventor: Hiroaki TAKASU, Chiba (JP)

(73) Assignee: SEIKO INSTRUMENTS INC., Chiba (JP)

(21) Appl. No.: 13/737,037

(22) Filed: Jan. 9, 2013

(30) Foreign Application Priority Data
Jan. 24, 2012 (JP) 2012-012317

(51) Int. Cl. H01L 27/06

(52) U.S. Cl. CPC H01L 27/0617
USPC 257/360

(57) ABSTRACT

In the semiconductor device including an ESD protection N-type MOS transistor having a sufficient ESD protective function, a drain region of the ESD protection N-type MOS transistor is electrically connected to a drain contact region via a drain extended region. The drain extended region is provided on a side surface and a lower surface of an ESD protection trench isolation region, and is formed of an impurity diffusion region of the same conductivity type as that of the drain region. The drain contact region is formed of an impurity diffusion region of the same conductivity type as that of the drain region.

### BACKGROUND OF THE INVENTION

1. Field of the Invention

The present invention relates to a semiconductor device including an electro-static discharge (ESD) protection element, which is formed between an external connection terminal and an internal circuit region in order to protect an internal element formed in the internal circuit region from being broken by ESD.

2. Description of the Related Art

In a semiconductor device including a MOS transistor, as an ESD protection element for preventing an internal circuit from being broken by static electricity from an external connection pad, an N-type MOS transistor which is provided so that a gate potential thereof is fixed to the ground (Vss) to be in an OFF state, that is, a so-called OFF transistor is known.

In order to prevent ESD breakdown of an internal circuit element, it is important to draw as large a proportion as possible of an electrostatic pulse into the OFF transistor but not to propagate the electrostatic pulse to the internal circuit element, or to change a fast and large electrostatic pulse into a slow and small signal before transmission.

Unlike the MOS transistors forming an internal circuit such as a logic circuit, the OFF transistor must be capable of running off the current completely at once caused by a large amount of captured electricity. Thus, the transistor width of the OFF transistor is in general set to be a large value of several hundreds of microns.

Accordingly, the occupation area of the OFF transistor is large, leading to a cause of an increase in the cost of the entire IC, in particular in a small IC chip.

An OFF transistor has in general a structure in which a plurality of drain regions, source regions, and gate electrodes are combined into a comb shape. Having a structure of a plurality of combined transistors, uniform operation in all of the ESD protection N-type MOS transistor is difficult to perform. For example, current concentration occurs in a region close to an external connection terminal, and an intended ESD protective function cannot be fully exercised, resulting in breakage.

As a countermeasure, increase of a distance between the contact hole on the drain region and the gate electrode is in particular effective in order to obtain a uniform current flow through the entire OFF transistor.

There has been proposed a case in which the distance between the contact hole on the drain region and the gate electrode is reduced as the distance from the external connection terminal becomes larger, to thereby increase the speed of operation of the transistor (see, for example, Japanese Published Patent Application H07-45829).

If the transistor width is reduced, however, in order to reduce the occupation area of the OFF transistor, a sufficient protective function cannot be exercised. Though the distance in the drain region between the contact and the gate electrode is adjusted so as to locally adjust the transistor operating speed in the above-mentioned improvement example, a desired distance from the contact to the gate electrode cannot be ensured because of the reduction of the width of the drain region. In order to exercise a sufficient protective function, on the other hand, it is necessary to increase the distance from the contact to the gate electrode, resulting in a problem in that the occupation area of the OFF transistor becomes larger.

### SUMMARY OF THE INVENTION

In order to solve the above-mentioned problem, a semiconductor device of the present invention is configured as follows.

According to an exemplary embodiment of the present invention, there is provided a semiconductor device, including: a plurality of MOS transistors including an ESD protection N-type MOS transistor; a trench isolation region provided between the plurality of MOS transistors, for electrically isolating the plurality of MOS transistors from each other; an ESD protection trench isolation region provided in contact with a drain region of the ESD protection N-type MOS transistor, the ESD protection trench isolation region having a vertical depth larger than a vertical depth of the trench isolation region; a drain extended region provided on a side surface and a lower surface of the ESD protection trench isolation region, the drain extended region being formed of an impurity diffusion region of the same conductivity type as a conductivity type of the drain region; and a drain contact region formed of an impurity diffusion region of the same conductivity type as the conductivity type of the drain region, the drain region of the ESD protection N-type MOS transistor being electrically connected to the drain contact region via the drain extended region.

Further, in the semiconductor device, a bottom surface of the ESD protection trench isolation region, which is provided in contact with the drain region of the ESD protection N-type MOS transistor and has the drain extended region on the side surface and the lower surface thereof, the drain extended region being formed of the impurity diffusion region of the same conductivity type as the conductivity type of the drain region, has a rounded corner shape.

Yet further, in the semiconductor device: the drain region of the ESD protection N-type MOS transistor is electrically connected to the drain contact region via the drain extended region, the drain extended region being provided on the side surface and the lower surface of the ESD protection trench isolation region and formed of the impurity diffusion region of the same conductivity type as the conductivity type of the drain region, the drain contact region being formed of the impurity diffusion region of the same conductivity type as the conductivity type of the drain region; and the semiconductor device further includes: another ESD protection trench isolation region formed in contact with a source region of the ESD protection N-type MOS transistor; a source extended region provided on a side surface and a lower surface of the another ESD protection trench isolation region held in contact with the source region, the source extended region being formed of an impurity diffusion region of the same conductivity type as a conductivity type of the source region; and a source contact region formed of an impurity diffusion region of the same conductivity type as the conductivity type of the source region, the source region of the ESD protection N-type MOS transistor being electrically connected to the source contact region via the source extended region.

By the above-mentioned measures, in the ESD protection N-type MOS transistor, the distance from the contact in the drain region or the source region to the gate electrode can be ensured while the increase in occupation area is minimized. Thus, local current concentration of the ESD protection N-type MOS transistor can be prevented to obtain a semiconductor device including an ESD protection N-type MOS transistor having a sufficient ESD protective function.

### BRIEF DESCRIPTION OF THE DRAWINGS

In the accompanying drawings:

FIG. 1 is a schematic cross-sectional view illustrating an ESD protection N-type MOS transistor of a semiconductor device according to a first embodiment of the present invention; and

FIG. 2 is a schematic cross-sectional view illustrating an ESD protection N-type MOS transistor of a semiconductor device according to a second embodiment of the present invention.

### DETAILED DESCRIPTION OF THE PREFERRED EMBODIMENTS

Referring to the accompanying drawings, the mode for carrying out the present invention is described below by way of embodiments.

### First Embodiment

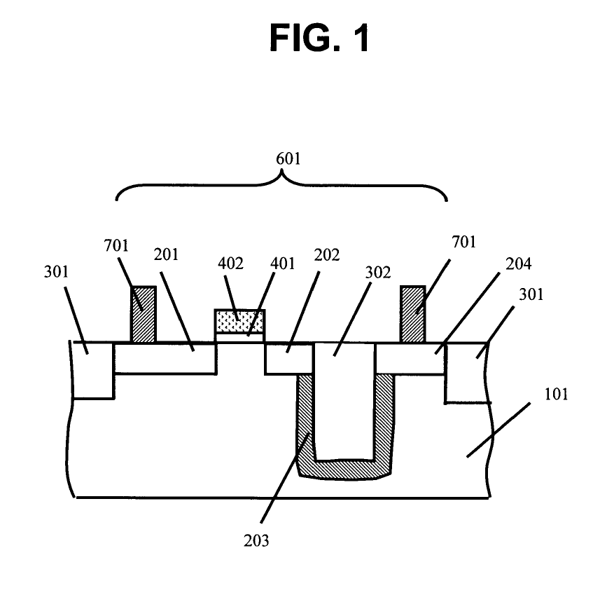

FIG. 1 is a schematic cross-sectional view illustrating an ESD protection N-type MOS transistor of a semiconductor device according to a first embodiment of the present invention.

On a P-type silicon substrate 101 as a semiconductor substrate of a first conductivity type, a source region 201 and a drain region 202 are formed of a pair of N-type heavily doped regions. Further, trench isolation regions 301 by shallow trench isolation are formed with respect to other elements, thereby achieving isolation.

Above a channel region of the P-type silicon substrate 101 between the source region 201 and the drain region 202, a gate electrode 402 made of a polysilicon film or the like is formed via a gate insulating film 401 made of a silicon oxide film or the like. In a region held in contact with the drain region 202, an ESD protection trench isolation region 302 is formed. The vertical depth of the ESD protection trench isolation region 302 is larger than the vertical depth of the trench isolation region 301 for element isolation.

Then, the drain region 202 is connected to a drain extended region 203. The drain extended region 203 is provided on a side surface and a bottom surface of the ESD protection trench isolation region 302, and is formed of an impurity diffusion region of the same conductivity type as that of the drain region 202.

The drain extended region 203 is further connected to a drain contact region 204. The drain contact region 204 is positioned on the side of the ESD protection trench isolation region 302 opposite to the drain region 202 and is formed of an impurity diffusion region of the same conductivity type as that of the drain region 202. On the drain contact region 204, a contact hole 701 embedded with metal wiring is formed. The above-mentioned structure forms an ESD protection N-type MOS transistor 601 according to the present invention.

With this structure, the distance from the edge of the gate electrode 402 in the drain region 202 to the contact hole 701 can be increased with a small occupation area as compared to the conventional case where the drain region is provided in plan. Thus, local current concentration can be suppressed to obtain an ESD protection N-type MOS transistor that operates uniformly in the entire transistor width. This structure can reduce the occupation area of the protective transistor with respect to the whole IC chip, thus saving the cost.

When the depth of the ESD protection trench isolation region 302, which is held in contact with the drain region 202, is set to be larger than the depth of the other trench isolation regions 301 for element isolation, a larger area reduction effect can be achieved. The depth of the ESD protection trench isolation region 302 can be controlled and formed independently from the other trench isolation regions 301 for element isolation, and hence the depths of the trench isolation regions 301 and the ESD protection trench isolation region 302 can be appropriately set depending on the specifications and purpose of a semiconductor product.

### Second Embodiment

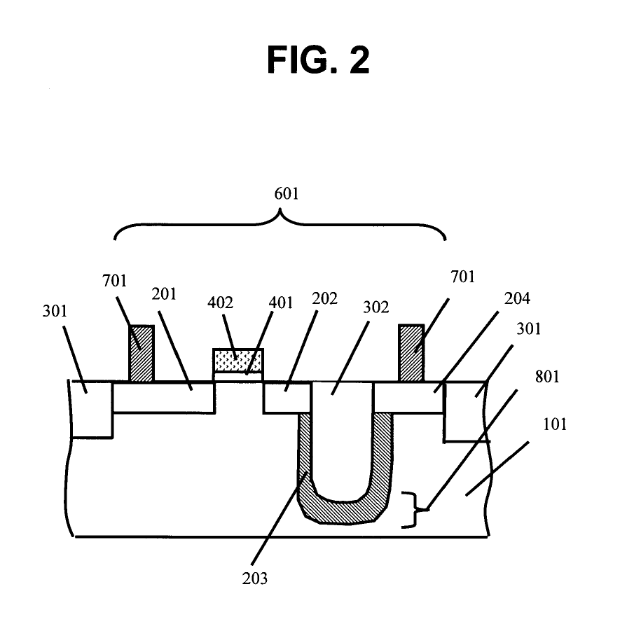

FIG. 2 is a schematic cross-sectional view illustrating an ESD protection N-type MOS transistor of a semiconductor device according to a second embodiment of the present invention.

The second embodiment is different from the first embodiment illustrated in FIG. 1 in that the bottom surface of the ESD protection trench isolation region 302 around which the drain extended region 203 is formed has rounded corners so that a rounded trench isolation region bottom surface 801 is formed.

In the case where a large forward current is applied from the outside, an effective drain region of an ESD protection N-type MOS transistor 601 for discharging the applied current as a forward current of a diode formed by junction of the N-type drain region and the P-type substrate of the ESD protection N-type MOS transistor 601 is a total region of the drain region 202, the drain extended region 203, and the drain contact region 204. As illustrated in FIG. 2, the bottom surface of the ESD protection trench isolation region 302 around which the drain extended region 203 is formed has the rounded corner shape, and hence the corner of the P-N junction portion is rounded. Thus, local current concentration can be prevented, and a large current can be discharged uniformly in the entire P-N junction portion. Other descriptions are the same as in the first embodiment illustrated in FIG. 1 with the same reference symbols.

In the first and second embodiments, by providing the drain extended region 203 only on the drain region 202 side of the ESD protection N-type MOS transistor 601, the distance from the edge of the gate electrode 402 in the drain region 202 to the contact hole 701 is increased more. Alternatively, although not illustrated, as necessary, in addition to and similarly to the drain region 202 side, the ESD protection trench isolation region 302 is formed also on the source region 201 side so as to be held in contact with the source region 201, and a source extended region is formed on a side surface and a bottom surface of the ESD protection trench isolation region 302 held in contact with the source region 201. Then, a source contact region is provided, which is positioned on the side of the ESD protection trench isolation region 302 opposite to the source region 201 and is formed of an impurity diffusion region of the same conductivity type as that of the source region 201. In this manner, the distance from the edge of the gate electrode 402 in the source region 201 to the contact hole 701 on the source side can be increased.

It is desired that the drain extended region 203 have, besides the same conductivity type of the drain region 202, the same sheet resistance value as that of the drain region 202 by adjusting the impurity concentration, the thickness, the width, and the like, because the current delay, unbalance, concentration, or the like can be further prevented.

By the above-mentioned measures, when the ESD protection N-type MOS transistor 601 performs bipolar operation, a large uniform and balanced current can be caused to flow. Thus, even when a large amount of current or pulse is applied from the outside, the entire transistor channel width of the ESD protection N-type MOS transistor 601 can be operated effectively to cause a current to flow effectively.

According to the present invention, the effective drain region of the ESD protection N-type MOS transistor 601 can be regarded as the total region of the drain region 202, the drain extended region 203, and the drain contact region 204. When a large forward current is applied from the outside, the applied current is discharged as the forward current of the diode formed by junction of the N-type drain region and the P-type substrate of the ESD protection N-type MOS transistor 601. In this case, a large P-N junction area can be obtained with a small surface occupation area because the effective drain region of the ESD protection N-type MOS transistor 601 of the present invention is the total region of the drain region 202, the drain extended region 203, and the drain contact region 204 as described above. Therefore, a large current is discharged rapidly.

In this manner, the semiconductor device including the ESD protection N-type MOS transistor 601 having a sufficient ESD protective function can be obtained.

Note that, the ESD protection N-type MOS transistor 601 having the conventional structure has been exemplified in the first and second embodiments for simple description. The ESD protection N-type MOS transistor 601 may have a double doped drain (DDD) structure or an offset drain structure.

As described above, according to the embodiments of the present invention, the semiconductor device including the ESD protection N-type MOS transistor 601 having a sufficient ESD protective function can be obtained with a small area.

What is claimed is:

1. A semiconductor device, comprising:
a plurality of MOS transistors including an ESD protection N-type MOS transistor;
a trench isolation region provided between the plurality of MOS transistors, for electrically isolating the plurality of MOS transistors from each other;
an ESD protection trench isolation region provided in contact with a drain region of the ESD protection N-type MOS transistor, the ESD protection trench isolation region having a vertical depth larger than a vertical depth of the trench isolation region;
a drain extended region provided on a side surface and a lower surface of the ESD protection trench isolation region, the drain extended region being formed of an impurity diffusion region of the same conductivity type as a conductivity type of the drain region; and
a drain contact region formed of an impurity diffusion region of the same conductivity type as the conductivity type of the drain region, the drain region of the ESD protection N-type MOS transistor being electrically connected to the drain contact region via the drain extended region.

2. A semiconductor device according to claim 1, wherein a bottom surface of the ESD protection trench isolation region has a rounded corner shape.

3. A semiconductor device according to claim 1, wherein the drain extended region has the same sheet resistance value as a sheet resistance value of the drain region.

4. A semiconductor device according to claim 1, further comprises:
another ESD protection trench isolation region provided in contact with a source region of the ESD protection N-type MOS transistor, the another ESD protection trench isolation region having a vertical depth larger than a vertical depth of the trench isolation region;
a source extended region provided on a side surface and a lower surface of the another ESD protection trench isolation region held in contact with the source region, the source extended region being formed of an impurity diffusion region of the same conductivity type as a conductivity type of the source region; and
a source contact region formed of an impurity diffusion region of the same conductivity type as the conductivity type of the source region,
the source region of the ESD protection N-type MOS transistor being electrically connected to the source contact region via the source extended region.

5. A semiconductor device according to claim 4, wherein the source extended region has the same sheet resistance value as a sheet resistance value of the source region.
